(19) United States
(12) Patent Application Publication
(10) Pub. No.: US 2019/0222038 A1
(43) Pub. Date: Jul. 18, 2019

(54) Portable Emergency Energy-Storage System with Intelligent Protection

(71) Applicant: Zhangsheng Chen, Shenzhen (CN)

(72) Inventor: Zhangsheng Chen, Shenzhen (CN)

(21) Appl. No.: 15/869,067

(22) Filed: Jan. 12, 2018

(51) Int. Cl. H02J 7/00; H02M 7/539; H05K 7/20; H01M 10/0525; H01M 10/42; H01M 10/48; H01M 10/613; H01M 10/6563; H01M 10/633; H01M 10/6551

(52) U.S. Cl. CPC H02J 7/0026; H01M 2010/4271; H05K 7/20136; H01M 10/0525; H01M 10/425; H01M 10/486; H01M 10/482; H01M 10/613; H01M 10/6563; H01M 10/633; H01M 10/6551; H02J 2007/0037; H02J 2007/004; H01M 2220/30; H02M 7/539

(57) ABSTRACT

The disclosure relates to a portable emergency energy-storage system with intelligent protection, including a power lithium battery pack, a charging management module, a deformation detecting and protecting module for lithium battery, a BMS protection module for lithium battery, an MCU module, an inverter module, a peak power output enhancement module, an output protection module, a temperature detecting module and an active cooling module. The MCU module and the BMS protection module for lithium battery provide double protection for the lithium battery pack on both hardware and software levels. The deformation detecting and protecting module for lithium battery is connected to the MCU module for monitoring whether the configuration of the lithium battery pack is within a safe range in real time so as to achieve a triple protection for the lithium battery pack. The disclosure has the following advantages: The disclosure provides double protection on both software and hardware levels for the security of entire system, so that the safety of the lithium battery is significantly improved without any significant increase in cost. Thus, the finished products will be more cost-effective.

### TECHNICAL FIELD

The disclosure relates to a portable emergency energy-storage system with intelligent protection, and more particularly to a portable emergency energy-storage power supply.

### BACKGROUND ART

Due to the exhaustion of non-renewable resources such as oil, countries all over the world have stepped up their efforts to replace the existing diesel vehicles with electric ones. The ensuing problem is the further shortage of electric power resources. The applications of distributed and portable energy-storage means will be widely spread in the future. As a clean energy, solar energy is an important part of human sustainable development. Solar power is an emerging renewable energy source. However, the traditional solution of effectively storing and fully utilizing solar energy is to use lead-acid batteries as energy-storage units. Since lead-acid batteries contain lead and other heavy metals, they cannot meet the human needs for further environmental protection on the planet. Another disadvantage of lead-acid batteries as energy-storage medium is that the self-discharge is too large to effectively store energy for a long time, and the portable property is worse due to the low energy density, bulky body and large area occupation. Another kind of power source that uses lithium batteries as energy-storage bodies solves many problems of the above-mentioned lead-acid power source with the advantages of eco-friendly lead-free attribute, higher energy density, small area occupation and excellent portability, etc. However, lithium batteries are active chemically. Therefore, their over discharge or charge in the absence of protection may cause damage to the batteries or fire, or even explosion.

The protection design and application of traditional portable energy-storage devices for lithium battery is not sufficient. The use of lithium ion batteries with low rate and poor uniformity has led to their lack of market acceptance due to the low safety and smaller set of functionality, which have seriously hindered the popularity of the technology or the finished products.

### SUMMARY

The technical problem to be solved in the disclosure is to overcome the above technical defects and to provide a highly secure portable emergency energy-storage system with intelligent protection.

In order to solve the above technical problem, the technical proposal provided by the disclosure is: a portable emergency energy-storage system with intelligent protection, including a power lithium battery pack, a charging management module, a deformation detecting and protecting module for lithium battery, a BMS protection module for lithium battery, an MCU module, an inverter module, a peak power output enhancement module, an output protection module, a temperature detecting module and an active cooling module. The MCU module is connected to the charging management module, the BMS protection module for lithium battery, the inverter module, the peak output enhancement module for inverter, the output protection module, the active cooling module, an indicating or warning module and an inverter switch to achieve intelligent control. The output protection module includes inverter output short circuit and overpower protections. The MCU module and the BMS protection module for lithium battery provide double protection for the lithium battery pack on both hardware and software levels. The deformation detecting and protecting module for lithium battery is connected to the MCU module for monitoring whether the configuration of the lithium battery pack is within a safe range in real time so as to achieve a triple protection for the lithium battery pack.

The MCU module may be divided into a system control and protection module and an inverter control and protection module. The system control and protection module realizes the charging and discharging management control, the temperature detection and protection and the user feedback processing to the lithium battery pack, and realizes a first intelligence protection of the lithium battery pack, including overcharge and over-discharge protections. The inverter control and protection module realizes the output to and the protection of the inverter module. The deformation detecting and protecting module for lithium battery includes a deformation detecting and sensing module for lithium battery. The MCU module receives signals from the deformation detecting and sensing module for lithium battery in real time to monitor whether the configuration of the lithium battery pack is within a safe range and protect it.

The charging module of the lithium battery pack supports solar panel charging, MPPT (Maximum Power-Point Tracking) solar charging, and adapter power charging or car cigarette lighter charging technologies.

The lithium battery pack is composed of a plurality of power lithium batteries connected in series and parallel.

The connection between the inverter module and the lithium battery pack realizes that the DC output from the lithium battery pack is converted into the AC output for the electric appliance operation. The inverter module is connected to a peak power output enhancement module to enhance the AC peak output power of the inverter module. The peak power output enhancement module is connected to an output protection module. The output protection module is controlled by the inverter control and protection module in the MCU module to achieve output protection, including short circuit protection, overpower protection and temperature protection.

The deformation detecting and sensing module for lithium battery is connected to the surface of the lithium ion battery of the lithium battery pack.

The system also includes a temperature detecting module, wherein one end of the temperature detecting module is connected to the lithium battery pack and the other end is connected to the MCU module. The active cooling module is connected to the MCU module. When the internal operating temperature of the system exceeds a pre-set safety value, the temperature detecting module sends feedback data to the MCU module, which drives the active cooling module to perform cooling.

It also includes a USB interface and a DC interface. One end of each of the USB interface and DC interface is connected to the MCU module. The other end of each of the USB interface and the DC interface is connected to the BMS protection module for lithium battery.

It also includes LED lights and a buzzer. The LED lights and the buzzer are respectively connected to the BMS protection module for lithium battery.

With the above structure, the disclosure has the following advantages: The disclosure provides a multi-protection intelligent technology for lithium battery energy-storage tank, first by using power lithium ion batteries with higher discharge rate, which is 10 or 20 times or more than that of ordinary lithium batteries, to greatly improve the uniformity of battery and reduce the heat value. The batteries according to the disclosure enable higher coefficient of safety in actual use and longer cycle life, and provide double protection on both software and hardware levels for the security of entire system, so that the safety of the lithium battery is significantly improved without any significant increase in cost. Thus, the finished products will be more cost-effective, which is beneficial to the popularization of the technology and finished products in the market.

### BRIEF DESCRIPTION OF THE DRAWINGS

FIG. 1 is a schematic structural diagram of the portable emergency energy-storage system with intelligent protection according to the disclosure;

FIG. 2 is a circuit diagram of the MCU module according to the disclosure;

FIG. 3 is a circuit diagram of the charging management module according to the disclosure;

FIG. 4 is a circuit diagram of the BMS protection module for lithium battery according to the disclosure;

FIG. 5 is a circuit diagram of the inverter module according to the disclosure;

FIG. 6 is the filter circuit for battery input according to the disclosure;

FIG. 7 is the primary booster circuit and rectifying circuit according to the disclosure;

FIG. 8 is the secondary inverter waveshaping circuit according to the disclosure;

FIG. 9 is a typical application circuit diagram of EG8010+1R2110S pure sine wave inverter according to the disclosure;

FIG. 10 is a circuit diagram of the peak power increase according to the disclosure;

FIG. 11 is a circuit diagram of the fan module according to the disclosure;

FIG. 12 is the EG8010 temperature detection circuit according to the disclosure;

FIG. 13 is the deformation detecting and sensing module for lithium battery according to the disclosure.

### DETAILED DESCRIPTION OF THE PREFERRED EMBODIMENTS

The disclosure will be further described in detail as follows with reference to the drawings.

The disclosure is based on the safe applications of lithium battery technology and provides a wealth of input and output, such as rich USB output and DC output. The built-in inverter module may convert the DC of lithium battery pack to AC output according to the disclosure. Furthermore, a new breakthrough may be achieved in the output peak power of inverter with the intelligently designed circuit, such that the battery can drive more domestic appliances, and the needs for emergency power supply both indoors and outdoors may be met.

The portable emergency energy-storage system with intelligent protection utilizes the MCU microcontroller as the main body, and realizes the protection towards the lithium battery on the software level and the protection on the hardware level using lithium battery protection module for the BMS of lithium battery. These two kinds of protection realize the multiple protection towards the lithium battery pack in the device according to the disclosure, including short circuit protection, overcharge and over-discharge protections and the like.

The lithium battery pack is composed of a plurality of power lithium batteries connected in series and parallel. For example, a battery pack voltage of 11.1V may be obtained with 3 batteries in series (3S), and higher capacity may be achieved with 3 batteries in parallel (3P). In the case of the said 3.7V lithium ion battery with a prioritized energy density of lithium battery that is higher, preferably the lithium ion battery with a discharge rate of 3C or higher, such as 10 Ah/3.7V, 10 Ah/11.1V may be obtained in a universal 3S manner while a higher capacity may be achieved through parallel connection, such as 3P & 3S, to get a battery capacity of 30 Ah/11.1V, 333 Wh.

The portable emergency energy-storage system with intelligent protection comprises a deformation detecting and sensing module for lithium ion battery and is connected to the surface of the lithium ion battery. The deformation detecting and sensing module for lithium ion battery is connected to an MCU microcontroller, wherein the deformation detecting and sensing module for lithium ion battery is used for deformation sensing and feedback on the cell of lithium ion battery, and the sensing head of the deformation detecting and sensing module for lithium ion battery is used for deformation sensing to the surface of the lithium ion battery. The deformation detecting and sensing module for lithium ion battery may also be used for monitoring the configuration safety of lithium ion battery. Once a danger is detected in the lithium ion battery, the module will send signal to the controller immediately to shut down all functions of the device, in order to prevent serious consequences such as a combustion or an explosion due to overcharge, and protect the safety of users' lives and properties.

One end of the temperature detecting module is connected to the lithium ion battery and the other end is connected to the MCU microcontroller. The temperature detecting module may be used for monitoring the temperature of lithium ion battery. Once the temperature exceeds the preset value or the temperature rises sharply, the controller will immediately shut down all functions of the device, in order to prevent serious consequences such as a combustion or an explosion due to overcharge, and protect the safety of users' lives and properties.

The system also includes a USB interface and/or a DC interface. One end of the USB interface and/or DC interface is connected to the controller. The other end of the USB interface and/or the DC interface is connected to the BMS protection module for lithium battery.

The connection between the inverter module and the lithium battery pack realizes that the DC output from the lithium battery pack is converted into the AC output for the electric appliance operation. The inverter module is connected to a peak power output enhancement module to enhance the AC peak output power of the inverter module. The peak power output enhancement module is connected to an output protection module. The output protection module is controlled by the inverter control and protection module in the MCU module to achieve output protection, including short circuit protection, overpower protection and temperature protection.

The peak power output enhancement module is provided with a intelligently designed circuit so that the peak power that the inverter module may output can be increased to 3-5 times the rated power, which applies to more traditional domestic appliances that require higher peak power to be driven, to enable richer application scenarios for the device and an increased operation stability for electric appliances.

The MCU module may be divided into a system control and protection module and an inverter control and protection module. The MCU unit in the system control and protection module uses BYD multi-cell lithium battery protection chip and possesses the functions of overcurrent, overvoltage, overcharge, over-discharge, short circuit and temperature protections and other functions. The circuit static power is 10-20 UA, making the standby time if the product longer. Preferably, the model number of the MCU is BM3451. The chip can be programmed and re-programmed. The MCU unit in the inverter control and protection module preferably uses the design scheme of high output conversion efficiency, and has the functions of overcurrent, overpower, overvoltage, overcharge, over-discharge, short circuit and temperature protections and other functions. The preferred embodiment is EGMICRO SPWM Sine Wave or Modified Sine Wave solutions.

The lithium battery pack is composed of a plurality of power lithium batteries connected in series and parallel. For example, a battery pack voltage of 11.1V may be obtained with 3 batteries in series, and higher capacity may be achieved with 3 batteries in parallel. In the case of the said 3.7V lithium ion battery with a prioritized energy density of lithium battery that is higher, such as 10 Ah/3.7V, 10 Ah/11.1V may be obtained in a universal 3S manner while a higher capacity may be achieved through parallel connection, such as 3P & 3S, to get a battery capacity of 30 Ah/11.1V, 333 Wh.

The deformation detecting and sensing module for lithium ion battery includes at least two deformation sensors arrayed on the cell surface of the lithium ion battery.

It also includes LED lights and a buzzer. The LED lights and the buzzer are respectively connected to the BMS protection module for lithium battery. In this technical proposal, the controller controls the battery management system (BMS) and the BMS controls the LED lights so as to achieve the On-SOS-Flashing function.

The system will be described in detail below with reference to the accompanying drawings:

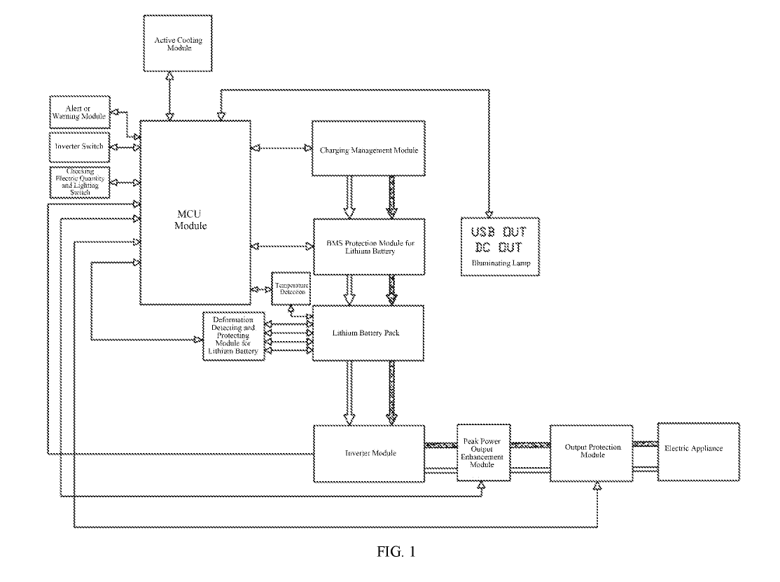

As shown in FIG. 1, a portable emergency energy-storage system with intelligent protection includes a power lithium battery pack, a charging management module, a deformation detecting and protecting module for lithium battery, a BMS protection module for lithium battery, an MCU module, an inverter module, a peak power output enhancement module, an output protection module, a temperature detecting module and an active cooling module. The MCU module is connected to the charging management module, the BMS protection module for lithium battery, the inverter module, the peak output enhancement module for inverter, the output protection module, the active cooling module, an indicating or warning module and an inverter switch to achieve intelligent control. The output protection module includes inverter output short circuit and overpower protections. The MCU module and the BMS protection module for lithium battery provide double protection for the lithium battery pack on both hardware and software levels. The deformation detecting and protecting module for lithium battery is connected to the MCU module for monitoring whether the configuration of the lithium battery pack is within a safe range in real time so as to achieve a triple protection for the lithium battery pack. The temperature detecting module is connected to the MCU module and the lithium battery pack for temperature monitoring of the lithium battery pack. The design of the BMS protection module for lithium battery supports USB, DC and illuminating lamp and other functions. The temperature probe of the active cooling module is in contact with the lithium battery pack and the associated heat-generating portion of the inverter module, and is connected to the MCU module to realize the real-time monitoring of the temperature inside the device of the disclosure. Once the temperature exceeds the safety value, the MCU module will activate the active cooling module to dissipate heat from the device of the disclosure. The positive and negative poles of the lithium battery pack are connected to the positive and negative poles of the input end of the inverter module to input the required DC into the inverter module. The inverter module converts DC into AC. The inverter module is connected to the peak power output enhancement module, which is connected to the output protection module. The output protection module is connected to the end user's electric appliance. The peak power output enhancement module may be used for enhancing the output power of the inverter to ensure a proper functioning of more electric appliances that require higher peak power to work effectively. The connecting to the output protection module may be used to provide protections such as AC output short circuit protection or output overpower protection.

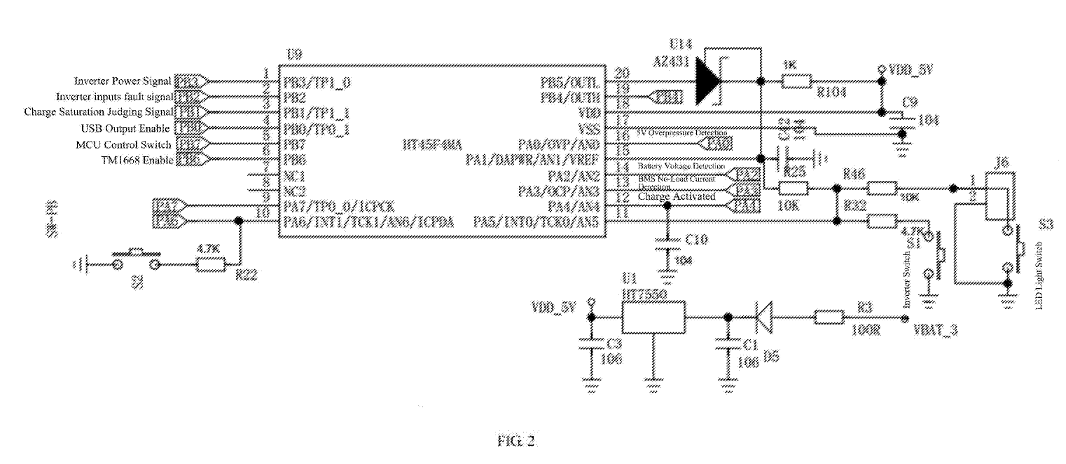

As shown in FIG. 2, the MCU module preferentially uses HOLTEK HT45F4MA, which has the advantages of multi-function, low power consumption and high computing speed. It also has the functions of high-precision battery indication, battery voltage detection, software protection of charge and discharge, intelligent detection of AC output and software temperature protection.

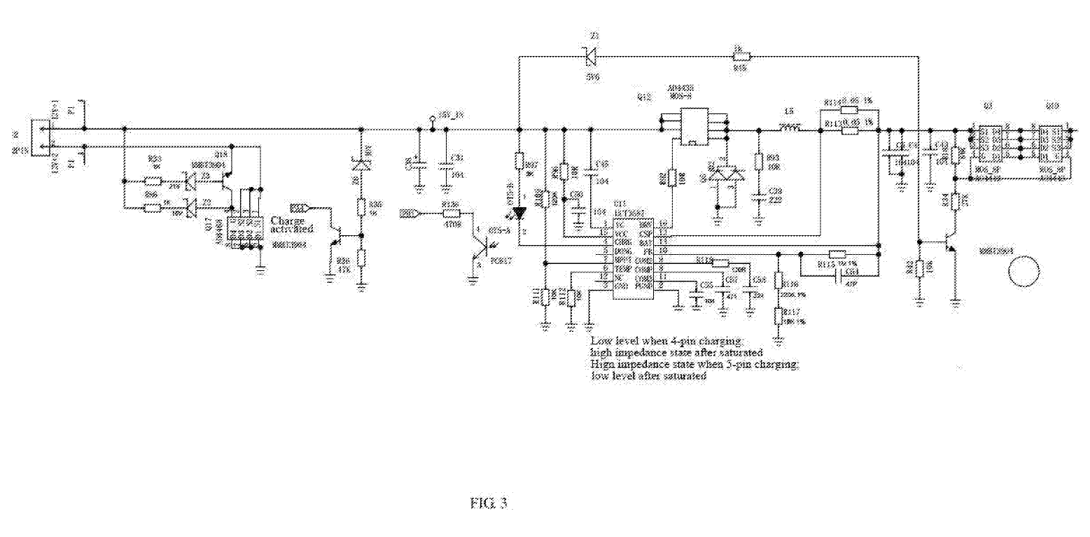

As shown in FIG. 3, the circuit diagram of intelligent charging management module of multi-cell power lithium ion battery, the charging module of the lithium battery pack is compatible with the AC power adapter and 12-24V/5A solar panel charging function, and is provided with MPPT intelligent charge management. The compatible intelligent charging management chip of multi-cell power lithium battery, preferably UCT3687, may achieve lithium battery charging with the trickle charge for low current, constant-current charge for high current, constant-voltage charge, temperature protection, overcurrent and overcharge protections and other functions. It simulates the process of safe charging of lithium batteries to improve battery life and product safety.

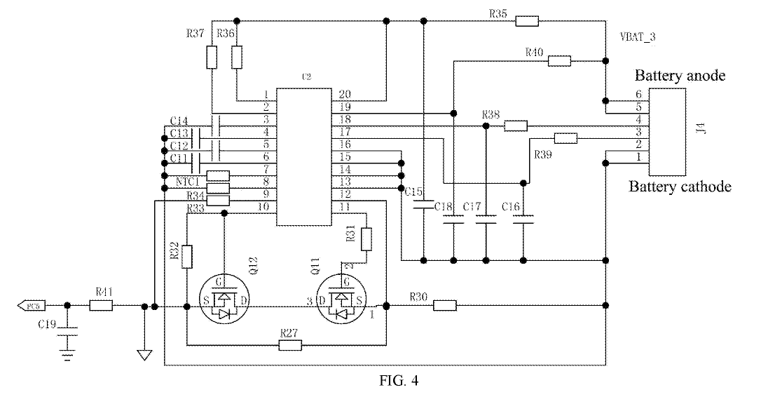

As shown in FIG. 4, the circuit diagram of BMS protection module for lithium battery, the BMS protection module for lithium battery uses BYD multi-cell lithium battery protection chip, and possesses the functions of overcurrent, overvoltage, overcharge, over-discharge, short circuit and temperature protections and others. The circuit static power is 10-20 UA, making the standby time if the product longer.

Overcurrent: R122 and R123 are overcurrent detection resistors. When the current is greater than the set value, the chip PIN 12 detects that the voltage is greater than the chip trigger voltage, and the PIN 11 is turned from high level to low level to turn off the discharging MOS transistor Q13.

Overcharge: When it is detected that the voltage of a single cell (VC1, VC2, VC3, VC4 and VC5 are input pins detecting the voltage of a single cell) is higher than the trigger voltage during charge, the PIN 10 is turned from high level to low level to turn off the discharging MOS transistor Q14.

Over-discharge: When it is detected that the voltage of a single cell (VC1, VC2, VC3, VC4 and VC5 are input pins detecting the voltage of a single cell) is lower than the trigger voltage during discharge, the PIN 11 is turned to low level to turn off the discharging MOS transistor Q13.

Temperature protection: PIN 7 is a temperature detection pin, which can detect the external temperature (mainly the external temperature of the battery) through the temperature resistor. When the battery temperature is higher than the set value during charge/discharge, the charge/discharge function will be turned off.

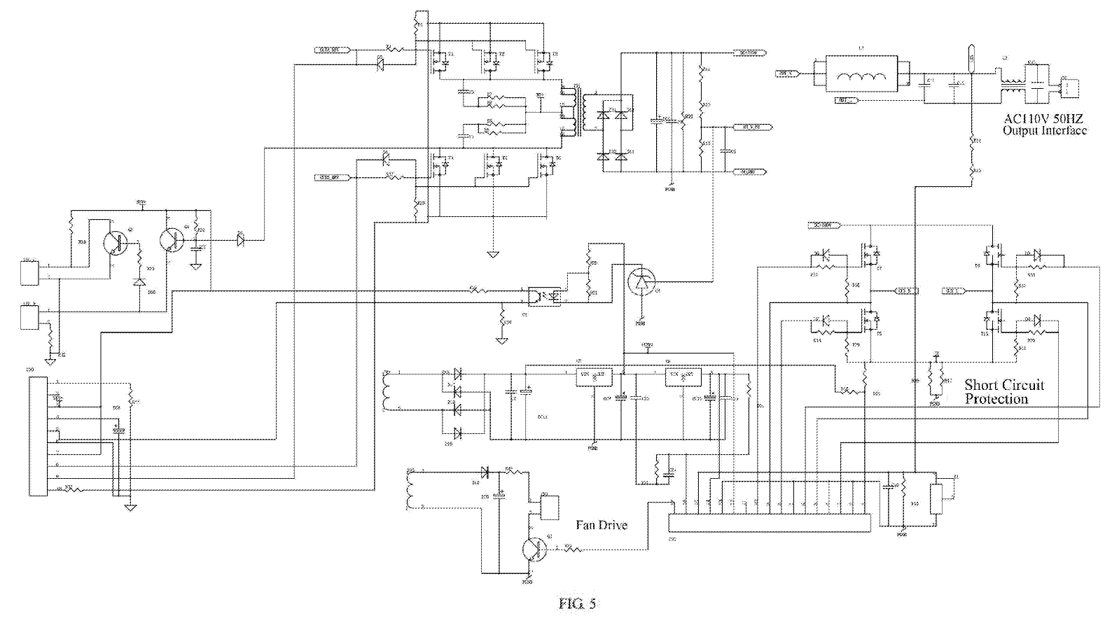

As shown in FIG. 5, the circuit diagram of inverter module, the inverter module is generally divided into a primary booster circuit, a rectifying circuit, a secondary inverter waveshaping circuit and a filter circuit for battery input;

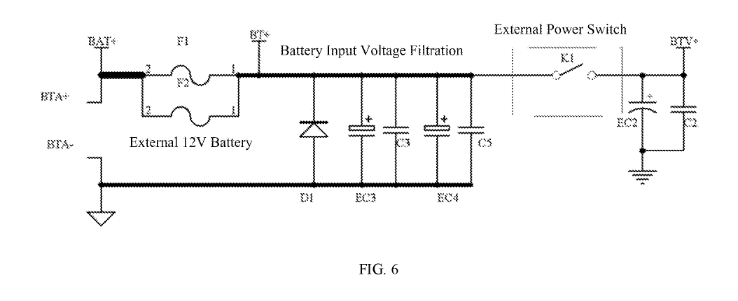

FIG. 6 is the filter circuit for battery input;

FIG. 7 is the primary booster circuit and rectifying circuit, wherein the primary booster circuit allows the battery DC 12V/24V to be boosted to the desired high voltage (between 150-380V) through TL494, which can provide overvoltage and undervoltage of the input voltage; the rectifying circuit is used to convert the AC flowing through the primary booster circuit into a high-voltage DC via the rectified voltage, usually by rectified current in the diode.

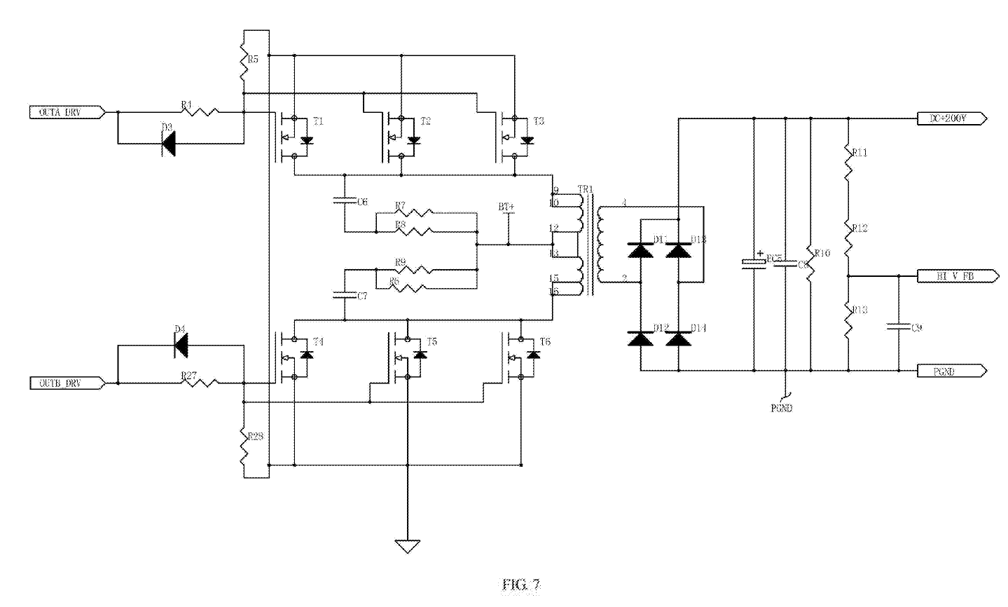

FIG. 8 is a secondary inverter waveshaping circuit. The secondary EGMICRO SPWM inverter module achieves the conversion from high-voltage DC to mains (sine wave AC). The SPWM module can be used for the transformation into the AC voltage with the desired frequency, and the control of the on-off of MOS transistors. The determined time is to define the on and off of the upper and lower power switching elements.

Intelligent output protection (overcurrent, overpower, short circuit, low voltage, high voltage, safety regulations and EMC protections, etc.) uses high-efficiency (>90) design, and possesses of the functions of overcurrent, overpower, over-voltage, overcharge, over-discharge, short circuit and temperature protections and others. It can output the sine wave that matches the power grid to enable richer application scenarios for the device.

The embodiment is EGMICRO SPWM Sine Wave solutions.

The primary TL494 implements the overvoltage (when the input voltage of battery is greater than 14V, TL494 computing comparator circuit detects that the value is greater than the set value, and thus enter the overvoltage protection mode in which the product does not output) and undervoltage (when the input voltage of battery is lower than 8.5V, TL494 computing comparator circuit detects that the value is lower than the set value, and thus enter the undervoltage protection mode in which the product does not output) features of the input voltage.

The secondary EGMICRO SPWM inverter module implements the over temperature, overpower (when the load power exceeds the calculator rated power and the power sampling resistor current is greater than the set value during AC output, the SPWM module turns off the output waveform; after the load power is removed, the SPWM module automatically restarts and the machine resumes output) and short circuit features (instantaneous power increase, the principle is the same as that of the overpower protection).

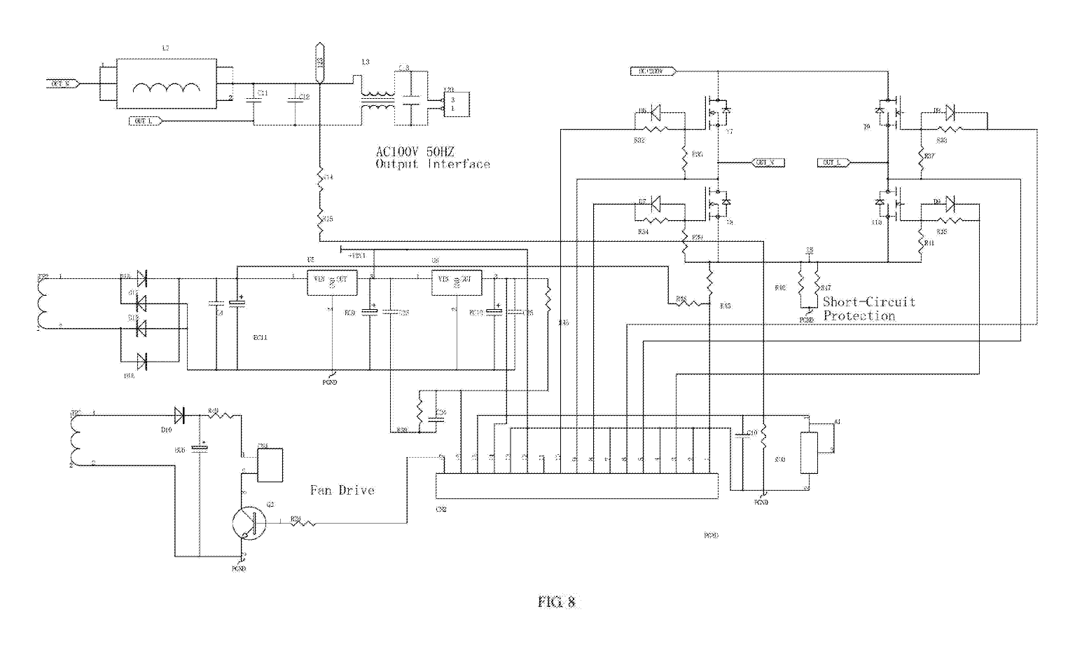

FIG. 9 is a typical application circuit diagram of EG8010+1R2110S pure sine wave inverter (monopolar modulation).

Peak Power Output Enhancement Module

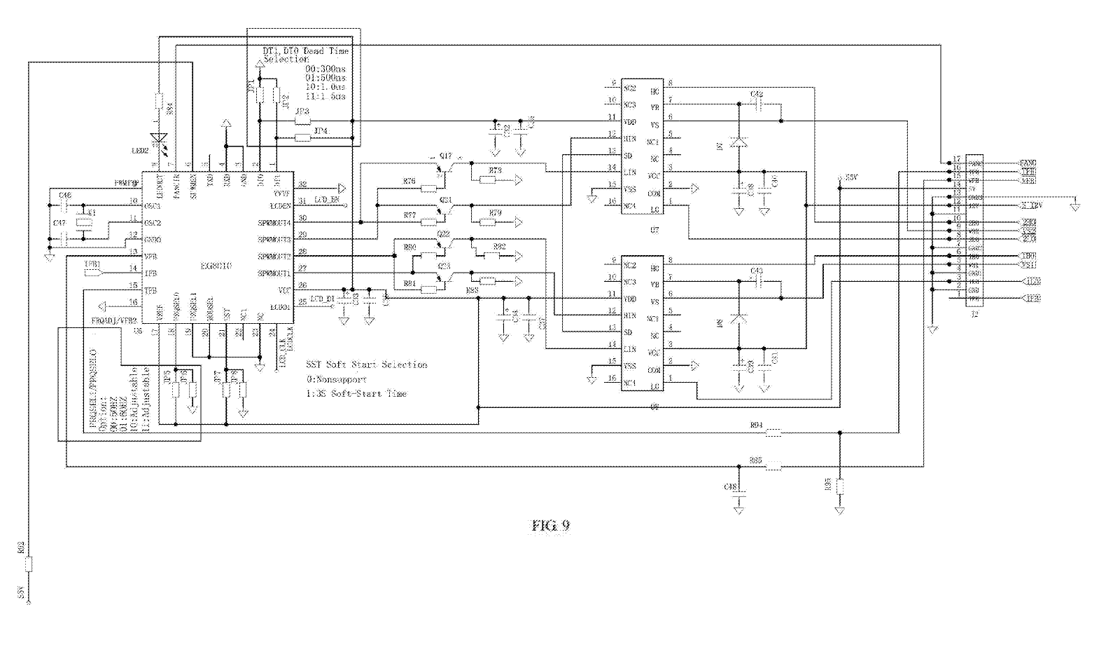

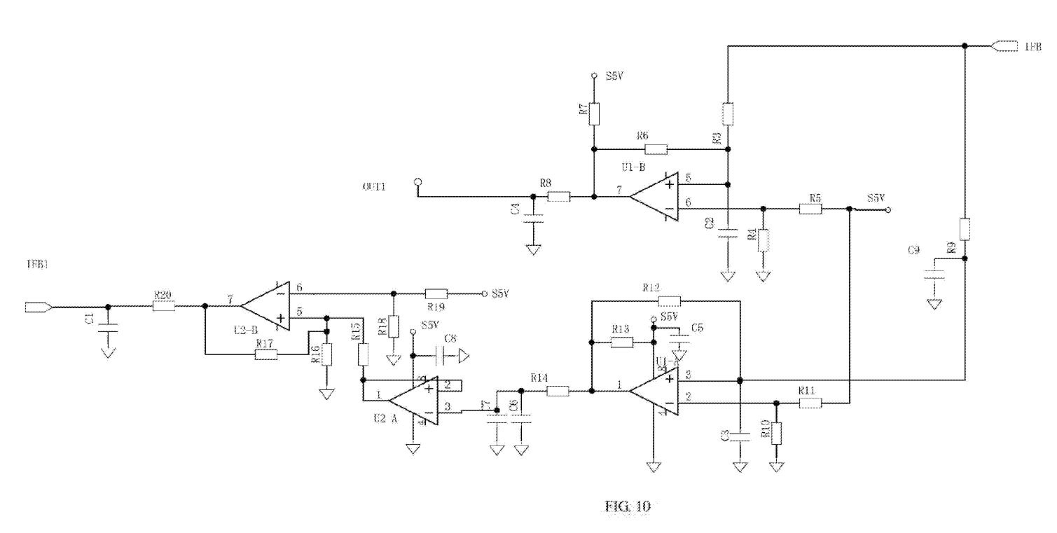

FIG. 10 is a circuit diagram of the peak power increase, in which a LM358 circuit is added. When it is detected that the load power exceeds the rated power, the prior operational amplifier LM393 sends a signal to the LM358 circuit. This LM358 circuit has the function of increasing the delay. R14 and C6 form a delay circuit, and the delay time is set to 3S.

Active Cooling Module

When it is detected that a temperature resistor placed on the MOS transistor and the cooling fin is higher than the set value at 85° C. (this is used in conjunction with temperature detection), the cooling fan begins to work. When the temperature is higher than 90° C., turn off the machine output. FIG. 11 is a circuit diagram of the fan module.

Temperature Detection

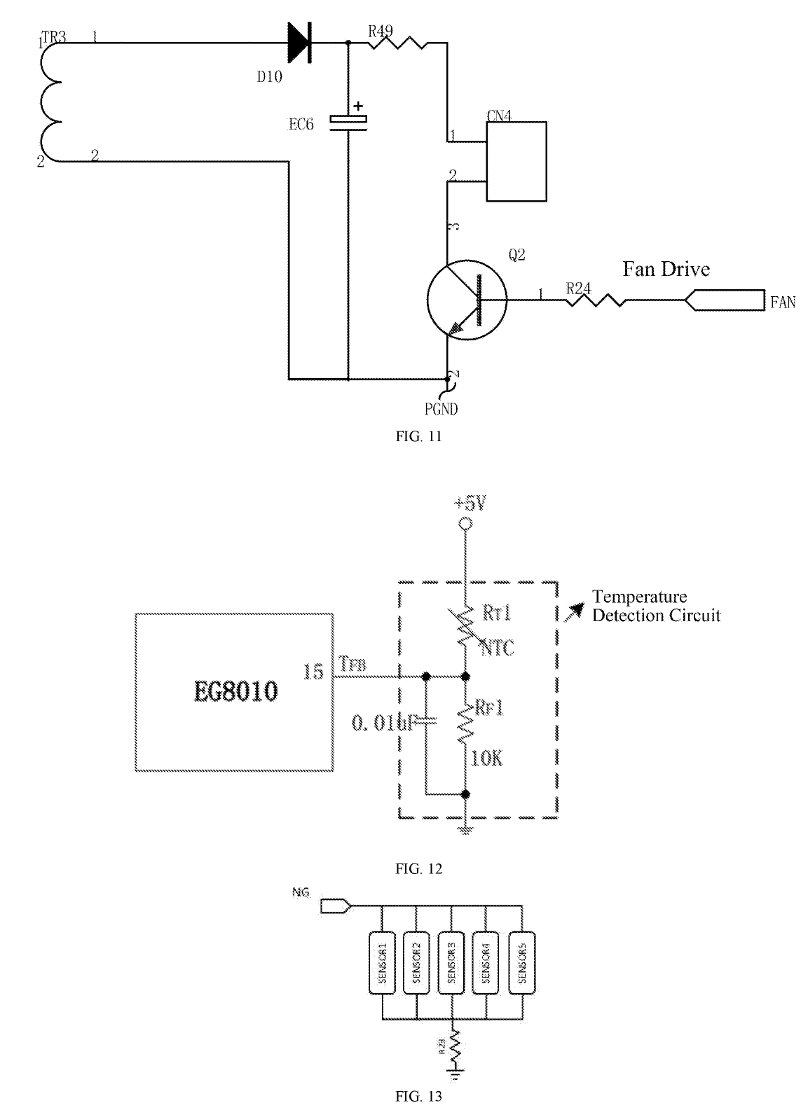

When the temperature is higher than the set value (85° C.), the TFB detects the trigger signal to drive the cooling fan to start working. FIG. 12 is an EG8010 temperature detection circuit.

As shown in FIG. 13, the deformation detecting and sensing module for lithium battery includes five deformation sensors arrayed in parallel on the cell surface of the lithium ion battery. As shown in FIG. 1, the portable start-up power supply includes a temperature detecting module, wherein one end of the temperature detecting module is connected to the lithium ion battery, and the other end is connected to the MCU microprocessor.

The descriptions for the disclosure and the embodiments thereof have no limitation; the embodiment shown in the drawings is only one of the embodiments of the disclosure, and the actual structure is not limited thereto. All in all, the structure modes and the embodiments similar to the technical solutions, which are designed by persons of ordinary skill in the art enlightened by above without creative efforts, shall fall within the protection scope of the disclosure.

1. A portable emergency energy-storage system with intelligent protection, wherein it includes a power lithium battery pack, a charging management module, a deformation detecting and protecting module for lithium battery, a BMS protection module for lithium battery, an MCU module, an inverter module, a peak power output enhancement module, an output protection module, a temperature detecting module and an active cooling module; the MCU module is connected to the charging management module, the BMS protection module for lithium battery, the inverter module, the peak output enhancement module for inverter, the output protection module, the active cooling module, an indicating or warning module and an inverter switch to achieve intelligent control; the output protection module includes inverter output short circuit and overpower protections; the MCU module and the BMS protection module for lithium battery provide double protection for the lithium battery pack on both hardware and software levels, and wherein the deformation detecting and protecting module for lithium battery is connected to the MCU module for monitoring whether the configuration of the lithium battery pack is within a safe range in real time so as to achieve a triple protection for the lithium battery pack.

2. The portable emergency energy-storage system with intelligent protection according to claim 1, wherein the MCU module may be divided into a system control and protection module and an inverter control and protection module; the system control and protection module realizes the charging and discharging management control, the temperature detection and protection and the user feedback processing to the lithium battery pack, and realizes a first intelligence protection of the lithium battery pack, including overcharge and over-discharge protections; the inverter control and protection module realizes the output to and the protection of the inverter module; the deformation detecting and protecting module for lithium battery includes a deformation detecting and sensing module for lithium battery, and wherein the MCU module receives signals from the deformation detecting and sensing module for lithium battery in real time to monitor whether the configuration of the lithium battery pack is within a safe range and protect it.

3. The portable emergency energy-storage system with intelligent protection according to claim 1, wherein the charging module of the lithium battery pack supports solar panel charging, MPPT (Maximum Power-Point Tracking) solar charging, and adapter power charging or car cigarette lighter charging technologies.

4. The portable emergency energy-storage system with intelligent protection according to claim 1, wherein the lithium battery pack is composed of a plurality of power lithium batteries connected in series and parallel.

5. The portable emergency energy-storage system with intelligent protection according to claim 2, wherein the connection between the inverter module and the lithium battery pack realizes that the DC output from the lithium battery pack is converted into the AC output for the electric appliance operation; the inverter module is connected to a peak power output enhancement module to enhance the AC peak output power of the inverter module; the peak power output enhancement module is connected to an output protection module, and wherein the output protection module is controlled by the inverter control and protection module in the MCU module to achieve output protection, including short circuit protection, overpower protection and temperature protection.

6. The portable emergency energy-storage system with intelligent protection according to claim 2, wherein the deformation detecting and sensing module for lithium battery is connected to the surface of the lithium ion battery of the lithium battery pack.

7. The portable emergency energy-storage system with intelligent protection according to claim 1, wherein the system also includes a temperature detecting module, wherein one end of the temperature detecting module is connected to the lithium battery pack and the other end is connected to the MCU module; the active cooling module is connected to the MCU module, and when the internal operating temperature of the system exceeds a pre-set safety value, the temperature detecting module sends feedback data to the MCU module, which drives the active cooling module to perform cooling.

8. The portable emergency energy-storage system with intelligent protection according to claim 1, wherein it also includes a USB interface and a DC interface, and one end of each of the USB interface and DC interface is connected to the MCU module, and wherein the other end of each of the USB interface and the DC interface is connected to the BMS protection module for lithium battery.

9. The portable emergency energy-storage system with intelligent protection according to claim 1, wherein it also includes LED lights and a buzzer, and wherein the LED lights and the buzzer are respectively connected to the BMS protection module for lithium battery.
